(19) United States
(12) Patent Application Publication
(10) Pub. No.: US 2007/0247182 A1
(43) Pub. Date: Oct. 25, 2007

(54) Protection of security key information

(76) Inventors: Timothy S. Beatty, Chandler, AZ (US); Mark N. Fullerton, Austin, TX (US); Tom J. Mozdzen, Gilbert, AZ (US)

Correspondence Address: CARRIE A. BOONE, P.C., 1110 NASA Parkway, SUITE 450, HOUSTON, TX, 77058, US

(21) Appl. No.: 11/395,871

(22) Filed: Mar. 31, 2006

(51) Int. Cl. H03K 19/00

(52) U.S. Cl. 326/8

(57) ABSTRACT

A protection circuit is disclosed, for preventing access to stored security key data after the security key is no longer used. The protection circuit performs operations on a programming circuit used to program a bit of the security key. The protection circuit prevents inspection of the security key bit, using several techniques. Subsequent inspection of the programming circuit does not reveal the value of the security key bit.

### TECHNICAL FIELD

This document relates to non-volatile data storage for processor-based systems and, more particularly, to the protection of such storage from inspection.

### BACKGROUND

Security is increasingly a part of processor-based systems, such as computers, cellphones, personal digital assistants (PDAs), and the like. Protecting private information stored on the processor-based system, or cryptography, typically involves encrypting the information, such that, only individuals with a “key” are able to access the information following encryption. Cryptography is used to protect credit card information, electronic mail, bank personal identification numbers (PINs), and so on.

The key, or security key, is generally a stream of bits of a predetermined length. Security keys may include any number of bits, such as 2048 bits. The bits making up the security key, or security bits, may be stored in the processor-based system. Or, the security key may be introduced into the processor-based system, such as by using a card key or other external device.

There are many mechanisms by which the security keys may be stored in the processor-based system. One method is to program a circuit that contains a programmable fuse corresponding to each bit of the security key. When the bit is programmed, the circuit changes the characteristics of the fuse, which produces an output value corresponding to the desired bit value. The process is irreversible: Once programmed, the information corresponding to the security key, or security key data, may not be changed again, and becomes permanent. Each circuit thus operates as a memory corresponding to each bit of the security key. Once the protected information is encrypted, access to the protected information is possible only by submission of the security key.

Because the permanent security key data is not stored in memory, it is unlikely that nefarious access to the data will occur. It may be possible for the programmable fuse circuit to be probed physically, electrically, or using software, to obtain the security key data. While the processor-based system is in the possession of the user, such piracy of the security key is unlikely.

In a consumer environment, however, processor-based systems rarely stay in a single user's possession indefinitely. Once the system is discarded, whether sold, donated, or thrown away, it may be possible that the security key data may be surreptitiously accessed, possibly enabling access to previously protected information.

Thus, there is a continuing need to maintain the privacy of permanent security key data even after possession of the processor-based system has been transferred.

### BRIEF DESCRIPTION OF THE DRAWINGS

The foregoing aspects and many of the attendant advantages of the subject matter described herein will become more readily appreciated as the same becomes better understood by reference to the following detailed description, when taken in conjunction with the accompanying drawings, wherein like reference numerals refer to like parts throughout the various views, unless otherwise specified.

FIG. 1 is a block diagram of a protection circuit, according to some embodiments;

FIG. 2 is a circuit diagram of the protection circuit of FIG. 1, according to some embodiments;

FIG. 3 is a flow diagram showing operation of the protection circuit of FIGS. 1 and 2, according to some embodiments; and

FIG. 4 is a block diagram of a system with the protection circuit of FIGS. 1 and 2, according to some embodiments.

### DETAILED DESCRIPTION

In accordance with the embodiments described herein, a protection circuit is disclosed, for preventing access to stored security key data after the security key is no longer used. The protection circuit performs operations on a programming circuit used to program a bit of the security key. The protection circuit prevents inspection of the security key bit, using several techniques. Subsequent inspection of the programming circuit does not reveal the value of the security bit.

In the following detailed description, reference is made to the accompanying drawings, which show by way of illustration specific embodiments in which the subject matter described herein may be practiced. However, it is to be understood that other embodiments will become apparent to those of ordinary skill in the art upon reading this disclosure. The following detailed description is, therefore, not to be construed in a limiting sense, as the scope of the subject matter is defined by the claims.

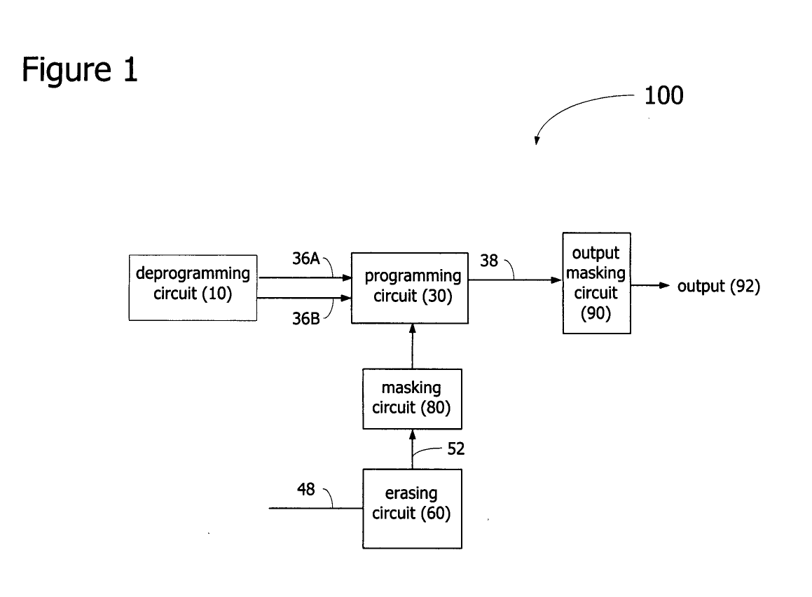

In FIG. 1, a block diagram of a protection circuit 100 is depicted, according to some embodiments. The protection circuit 100 includes a programming circuit 30, an erasing circuit 60, a deprogramming circuit, a masking circuit 80, and an output masking circuit 90.

The programming circuit 30 is used to program a bit of a security key. The bit may be a non-volatile storage location, such as non-volatile read-only memory, also known as NVROM, as one example. The programming circuit 30 may be implemented in a number of ways. Generally, however, the programming circuit 30 includes one or more programmable inputs, enabling the circuit to be activated, and a digital output that corresponds to the intended state or value of the bit of the security key. The programming circuit 30 of FIG. 1 features inputs 36A and 36B and output 38. Optionally, the programming circuit 30 may be designed so that it may be programmed only once.

The erasing circuit 60 is used to indicate that the bit of the security key is no longer valid. The erasing circuit 60 may include one or more programmable inputs, to activate the circuit, and a digital output that corresponds to the validity of the security key bit. Thus, for example, where the bit is in NVROM, the erasing circuit 60 indicates whether the NVROM location is valid or not as the value of the security key bit, without any write to the NVROM location occurring. The erasing circuit 60 of FIG. 1 features an input 48 and an output 52. As with the programming circuit 30, the erasing circuit 60 may optionally be designed so that it may be programmed only once.

Although the erasing circuit 60, in essence, indicates that the programming circuit 30 is no longer valid, the programming circuit 30 may continue to have information about the security key bit even after the erasing circuit 60 has been programmed to invalidate the bit. The circuitry making up the programming circuit 30 may be inspected, providing information about the programmed state. This may be true when the programming circuit 30 includes dynamic circuit elements, such as fuses, in which the circuit element in a first state indicates a first output value and the circuit element in a second state indicates a second output value. Thus, a physical inspection of the programming circuit 30 may provide evidence of the security key bit value long after the security key is no longer used. Or, the programming circuit 30 may be electrically scanned to uncover evidence of the programming state. Software may be executed to detect the programmed state. Other probing techniques relying on electromagnetic radiation and other physical means may uncover the programmed state. As used herein, the aforementioned techniques are referred to as “inspection” of the programming circuit 30.

The deprogramming circuit 10 is connected to the inputs 36A and 36B of the programming circuit 30. The deprogramming circuit 10 is used to alter the output 38 of the programming circuit 30 by programming the circuit differently than the way the circuit was originally programmed. Thus, where the programming circuit 30 includes dynamic circuit elements, such as fuses, the deprogramming circuit 10 may modify all of the dynamic circuit elements (where originally only one dynamic circuit element was modified). This may confound the inspection of the programming circuit 30 to ascertain its original programming state.

As dynamic circuit elements, or circuits whose characteristics change, fuses exist in many forms. Some fuses break when programmed, where the programming includes transmitting a predetermined current through the fuse. Other fuses become more resistant when programmed. Still others become less resistant when programmed. Some fuses, for example, may be referred to as “anti-fuses.” In all instances, some characteristic of the fuse changes in a measurable way. As used herein, the term “fuse” is not limited to any one type of fuse, but may include any variety of fuse, including those known as “anti-fuses,” and, further, including those not described particularly herein. The phrase “programming the fuse” and similar phrases used herein are meant to describe any action taken that changes the characteristic of the fuse.

The masking circuit 80 is connected between the programming circuit 30 and the erasing circuit 60. By sending a signal or signals to the programming circuit 30, the masking circuit 80 is used to “corrupt” or mask the programming circuit 30 from within the circuit, by changing some characteristic of the circuit so that the value at the output 38 changes. Because the programming circuit 30 may have one of a number of possible configurations, the masking circuit 80 is tailored to the particular circuit arrangement of the programming circuit 30. The erasing circuit 60 is connected to the masking circuit 80, as its output 52 has a known value that may be used by the masking circuit 80 to mask the programming circuit 30.

The output mask circuit 90 is connected to the output 38 of the programming circuit 30. The output mask circuit 90 is used to mask the output 38 of the programming circuit. By changing the output 38 of the programming circuit 30, the value of the security key bit may be more difficult to ascertain.

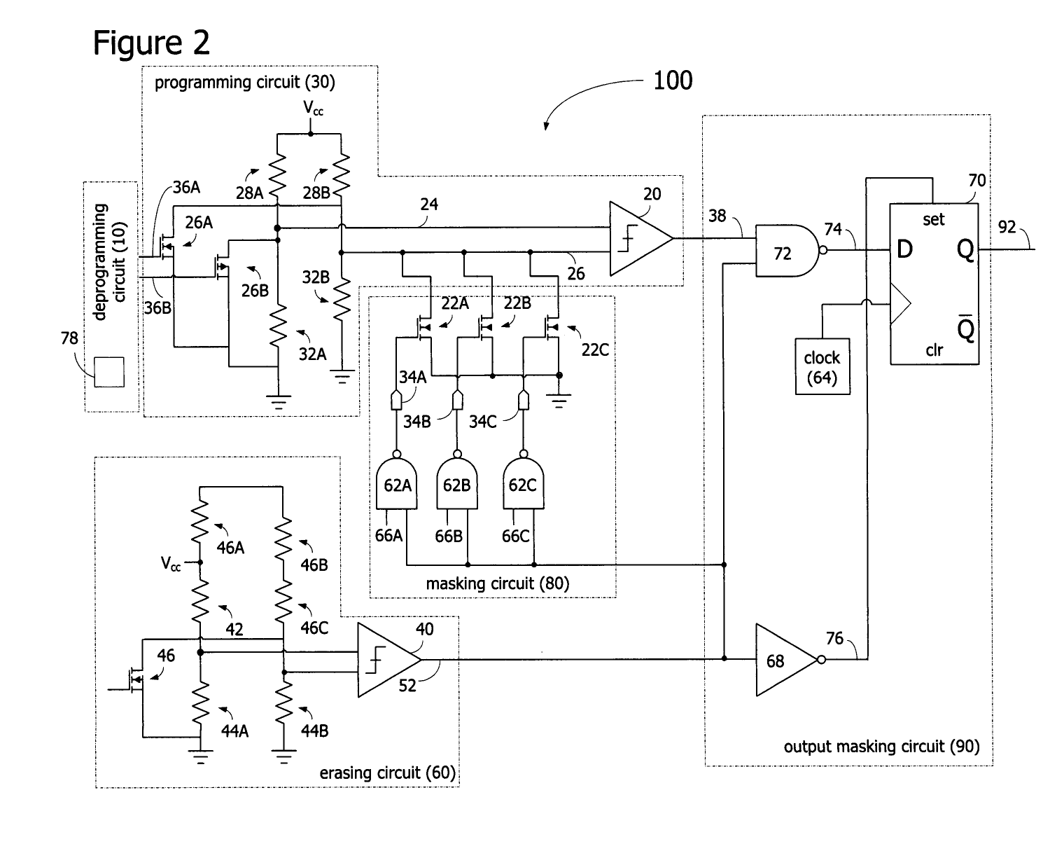

One possible implementation of the protection circuit 100 is depicted in FIG. 2, according to some embodiments. The protection circuit 100 includes the programming circuit 30, the erasing circuit 60, the deprogramming circuit 10, the masking circuit 80 and the output masking circuit 90.

In some embodiments, the programming circuit 30 includes differential inputs 36A and 36B, a first fuse network (including a transistor 26A, a fuse 28A, and a bias resistor 32A), a second fuse network (including a transistor 26B, a fuse 28B, and a bias resistor 32B), a comparator 20, and an output 38. A source voltage, V_{cc}, drives the circuit 30. When differential input 36A is activated, the transistor 26A is programmed, causing the fuse 28A to be programmed; likewise, when differential input 36B is activated, the transistor 26B is programmed, causing the fuse 28B to be programmed. When the fuse 28A is programmed, the output 38 may be zero (one); when the fuse 28B is programmed, the output 38 may be one (zero). The reference voltage for the comparator 20 is generated by the ratio of the fuse 28A (28B) to the resistor 32A (32B). Programming the fuse consists of altering the properties of the device 28A (28B) in order to permanently change its electrical resistance.

In some embodiments, the erasing circuit 60 includes a single-ended input 48, a transistor 46, a fuse 42, reference fuses 46A, 46B, and 46C, bias resistors 44A and 44B, and a comparator 40, to produce an output 52. A source voltage, V_{cc}, drives the circuit 60. The erasing circuit 60 is used to indicate that the security key bit is no longer valid. Thus, the programming circuit 30 is programmed when the security key bit is being designated (either a logic one or a logic zero) while the erasing circuit 60 is programmed when the security key bit is no longer being used. Initially, the erasing circuit 60 has an output 52 of zero, indicating that the security key data is active. Once the security key data is no longer used, the input 46 of the erasing circuit 60 is activated, which programs the fuse 42, causing the output 52 to change to a one. The erasing circuit 60 is not technically “erasing” the bit of the security key, but is constructively representing the erasure of the bit.

A circuit 30 and a circuit 60 may be associated with each bit of the security key. (Security keys may be 256 bits in length, as one example.) The erasing circuit 60 is depicted as a single-ended fuse circuit while the programming circuit 30 is depicted as a differential circuit. However, there is a variety of ways in which each of these circuits may be arranged to perform the function of programming and “erasing” the security key bit.

The deprogramming circuit 10 deprograms the programming circuit 30 by writing a value to the differential inputs 36A and 36B, the value being opposite to the value written during the original programming of the circuit 30. The deprogramming circuit 10 thus causes the un-programmed fuse of the programming circuit 30 to be programmed. By programming both fuses, an inspection of the circuit will no longer provide information about the value of the security key bit.

Although both fuses 36A and 36B are programmed, the technique of programming the un-programmed fuse by the deprogramming circuit 10 (some time after the original fuse was programmed) may not be electrically determinate, and thus may not fully protect against inspection. It may not be possible to guarantee the resistance in the fuse 36A will be the same as the resistance in the fuse 36B following execution of the deprogramming circuit 10. Thus, the physical characteristics of the programmed fuse 36A may be different from the physical characteristics of the programmed fuse 36B. It may be possible from this difference to ascertain which fuse was programmed first.

To address this concern, the deprogramming circuit 10 may optionally include an algorithm 78 to randomly vary the time taken to program the un-programmed fuse of the programming circuit 30. The algorithm 78 may be a software program, as one example, a hardware circuit, or a combination of software and hardware. The algorithm 78 may make it more difficult to determine which fuse was originally programmed, as the technique removes the systematic bias that may occur between the two fuse programming events.

Additionally, the protection circuit 100 includes the output masking circuit 90 to protect against inspection of the security key bit. In some embodiments, the output masking circuit 90 includes a two-input NAND gate 72, which receives the signal 38 (the output from the comparator 20 of the programming circuit 30) and the signal 52 (the output from the comparator 40 of the erasing circuit 60). In some embodiments, the output 52 (from the erasing circuit 60) is logic zero, indicating that the security key bit has been erased. The signal 52 into the NAND gate 72 thus ensures that a signal 74 coming out of the NAND gate 72 is logic one. In this manner, the value of the signal 38 from the programming circuit 30 is masked.

In addition to the NAND gate 72, the output masking circuit 90 includes an inverter 68 and a D flip-flop 70, driven by a clock 64. The signal 74 is fed into the D flip-flop 70. The D flip-flop 70 is driven by the clock 64, such that the signal 74 passes through as the output 92, delayed by a clock cycle. Also coupled to the output 52, an inverter 68 converts the polarity of the output 52, producing signal 76, which is used to reset the D flip-flop asynchronously so that the value of the output 92 from the D flip-flop 70 is always a logic one. The circuitry in the output masking circuit 90 thus further confounds the ability to determine the security bit value by masking the output 38 of the programming circuit 30.

The protection circuit 100 thus provides multiple protections against obtaining security key information by inspecting the programming circuit 30. However, it may be possible that a probe is placed, not on the output of the programming circuit 30, but on one of the inputs 24 or 26 to the comparator 20. Accordingly, the masking circuit 80 is connected to the input 26 to the comparator 20. The masking circuit 80 includes two-input NAND gates 62A, 62B, and 62C. A first input of each NAND gate is connected to the output 52 of the erasing circuit 60. A second input of NAND gate 62A, 62B, and 62C is connected to programmable inputs 66A, 66B, and 66C, respectively.

The masking circuit 80 also includes transistors 22A-C and input terminals 34A-C. The terminals 34A-C are connected to an input 26 to the comparator 20 of the programming circuit 30. The transistors 22A-C are logically scaled transistors that may be activated by enabling the input terminals 34A-C, to test the dynamic range between an unprogrammed and a programmed fuse. The masking circuit 80 may be programmed so that the comparator 20 thinks the fuse 28A (28B) was programmed. Or, once a fuse is programmed, the masking circuit 80 may be programmed to test whether the comparator 20 will change the output 38. Where fuse 28B is programmed, for example, the input terminals 34A, 34B, and 34C may be activated, to see whether the output 38 of the comparator 20 changes. If there is enough dynamic range between the fuses when one is programmed, then activating input terminals connected to the input 24 to the comparator (not shown) would result in no change; if there is not enough dynamic range, activating the additional input terminals would cause the output to change, indicating that the circuit 30 is not working properly.

In FIG. 2, the outputs of each NAND gate 62A, 62B, and 62C are connected to the input terminals 34A, 34B, and 34C, respectively, which drive logarithmically scaled transistors 22A, 22B, and 22C, as shown. Alternatively, the masking circuit 80 may be connected to the input 24 to the comparator 20 (not shown). Because the output 52 from the erasing circuit 60 is a logic zero, the output of the NAND gates 62A, 62B, and 62C will be a one (irrespective of any values programmed into the programmable inputs 66A, 66B, and 66C). Thus, the transistors 22A, 22B, and 22C will cause a change in the analog voltage, causing the output 38 of the comparator 20 to change and favor a known value unrelated to the previously programmed value. By programming the erasing circuit 60, the input terminals 34A, 34B, and 34C will force the programming circuit 30 to a certain value and force the transition to a preferred and known state. This prevents an electrical or emission probe from determining the originally programmed value. It also thwarts power analysis techniques that might be used to determine the original bit value of the security key.

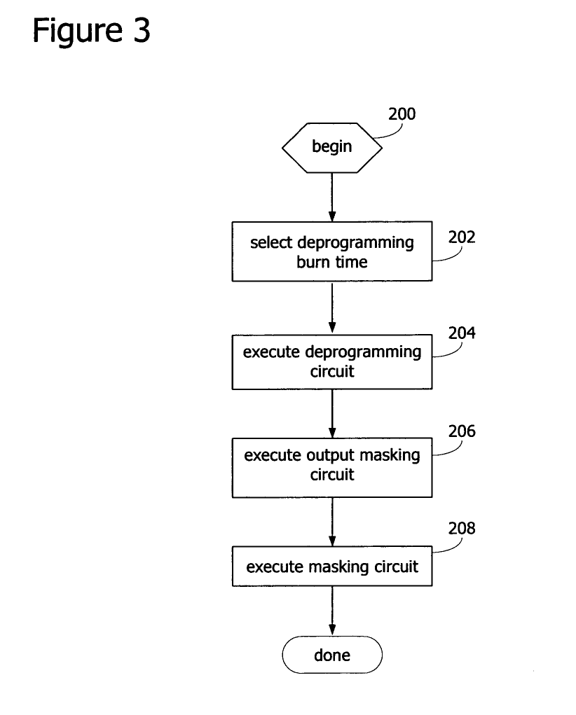

In FIG. 3, a flow diagram 200 depicts a method of operating the protective circuit 100, according to some embodiments. While the flow diagram 200 includes operations occurring in a particular arrangement, the order of operations may be changed. Further, the operations are depicted as occurring sequentially, while many of the operations may be performed simultaneously, or in parallel. Other operations not included in the flow diagram 200 may occur in between the operations depicted. Engineers of ordinary skill in the art will recognize a number of implementation possibilities. The operations in FIG. 3 that describe “execution” of a circuit may include software execution, hardware execution, or a combination of hardware and software execution.

The flow diagram 200 begins by selecting a time for deprogramming the programming circuit 30, such as by programming the unprogrammed fuse 28A (28B) in FIG. 3 (block 202). This may be achieved using an algorithm with a random number generator or other algorithm, and is used to thwart distinguishing the later fuse programming operation from the original fuse programming operation. The deprogramming circuit 10 is executed to deprogram the programming circuit 30 (block 204). In some embodiments, the deprogramming circuit 10 programs the inputs 36A and 36B to the opposite value used to originally program the first fuse. The effect will be to program the second fuse, which may make the programming circuit 30 indeterminate. For further protection, the output 38 of the programming circuit 30 is masked by feeding the output 38 and the output 52 of the erasing logic 60 into the output masking circuit 90 (block 206), such that the signal 74 is always a logic one or a logic zero, in other words, determinate. One input to the comparator 20 of the programming circuit 30 is changed, by executing the masking circuit 80 (block 208), such that the output 38 of the programming circuit 30 will change to a predetermined logic value.

By programming both fuses 28A and 28B of the programming circuit 30, logically combining the output 38 with another value (output 52 of the erasing circuit 60), and changing one of the inputs to the comparator 20, the protection circuit 100 impairs the ability to ascertain the original value of the security key bit from the programming circuit 30, in some embodiments. The protection circuit 100 may further include logic to randomly vary the programming time of the second fuse during deprogramming, as additional protection against discovery of the original security key.

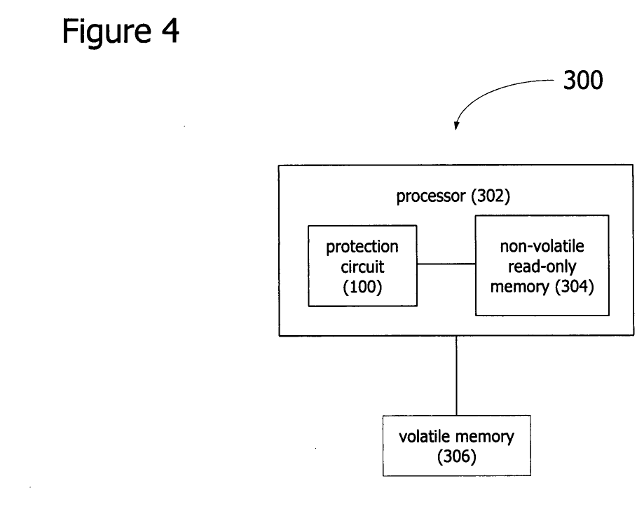

The protection circuit 100 may be part of a processor-based system. In FIG. 4, a processor-based system 300 is depicted, including a processor 302, including the protection circuit 100 and a non-volatile read-only memory 304, and a volatile memory 306. The non-volatile read-only memory 304 is used to store the security bit value. The protection circuit 100 obfuscates inspection of the programming circuit 30, such as after the processor-based system 300 is no longer in the possession of the owner using the security key.

While the subject matter has been described with respect to a limited number of embodiments, those skilled in the art will appreciate numerous modifications and variations therefrom. It is intended that the appended claims cover all such modifications and variations as fall within the true spirit and scope of the subject matter.

We claim:

1. A circuit, comprising:
a first circuit to generate a logic value; and
a second circuit to prevent inspection of the first circuit to determine the logic value.

2. The circuit of claim 1, the first circuit further comprising a first dynamic circuit element and a second dynamic circuit element, the first dynamic circuit element having been programmed, the second circuit further comprising:
a deprogramming circuit to program the second dynamic circuit element.

3. The circuit of claim 1, the first circuit further comprising an output, the logic value to be sent to the output, the second circuit further comprising:
an output masking circuit connected to the output, the output masking circuit to receive the logic value and to generate a second logic value, wherein the second logic value is not equal to the logic value.

4. The circuit of claim 1, the first circuit further comprising a first dynamic circuit element and a second dynamic circuit element, the first dynamic circuit element, when programmed, to generate a first logic value, the second dynamic circuit, when programmed, to generate a second logic value, the second circuit further comprising:
a masking circuit connected to the first circuit, the second circuit to cause the first circuit to generate the second logic value even though the first dynamic circuit is programmed and the second dynamic circuit is not programmed.

5. The circuit of claim 2, the deprogramming circuit to program the second dynamic circuit element for a predetermined time, the deprogramming circuit further comprising:
an algorithm to vary the predetermined time.

6. The circuit of claim 4, wherein the first dynamic circuit element comprises a first fuse and the second dynamic circuit element comprises a second fuse.

7. The circuit of claim 1, further comprising:
an erasing circuit to generate an erase output, the erase output to indicate that the logic value is not valid.

8. The circuit of claim 7, wherein the erase output is coupled to the masking circuit.

9. A method, comprising:
generating a logic value by a first circuit;
executing a second circuit, the second circuit to prevent inspection of the first circuit to determine the logic value.

10. The method of claim 9, generating a logic value by a first circuit further comprising:
programming a first dynamic circuit element of the first circuit to generate a first logic value.

11. The method of claim 9, executing a second circuit further comprising:
programming a first dynamic circuit element, the first circuit comprising the first dynamic circuit element and a second dynamic circuit element;
wherein the second dynamic circuit element is programmed.

12. The method of claim 9, executing a second circuit further comprising:
receiving the logic value; and
generating a second logic value;
wherein the second logic value is not equal to the logic value.

13. The method of claim 9, executing a second circuit further comprising:
sending a signal to the first circuit, the first circuit comprising a first dynamic circuit element and a second dynamic circuit element, the first dynamic circuit element, when programmed, to generate a first logic value, the second dynamic circuit, when programmed, to generate a second logic value, wherein the signal causes the first circuit to generate the second logic value even though the second dynamic circuit is not programmed.

14. The method of claim 11, programming a first dynamic circuit element further comprising programming a first fuse.

15. The method of claim 11, programming a first dynamic circuit element further comprising:
executing an algorithm to determine a programming time of the first dynamic circuit element.

16. A system, comprising:
a processor to execute instructions, the processor comprising a protection circuit and a non-volatile storage; and
a volatile memory to store the instructions; the protection circuit comprising:
a first circuit to generate a logic value; and
a second circuit to prevent inspection of the first circuit to determine the logic value.

17. The system of claim 16, the second circuit further comprising:
an output masking circuit connected to an output of the first circuit, the logic value to be sent to the output, the output masking circuit to receive the logic value and to generate a second logic value, wherein the second logic value is not equal to the logic value.

18. The system of claim 16, the first circuit further comprising:
a first dynamic circuit element and a second dynamic circuit element, the first dynamic circuit element, when programmed, to generate a first logic value, the second dynamic circuit, when programmed, to generate a second logic value.

19. The system of claim 18, the second circuit further comprising:
a masking circuit connected to the first circuit, the second circuit to cause the first circuit to generate the second logic value even though the first dynamic circuit is programmed and the second dynamic circuit is not programmed.

20. The system of claim 16, the first circuit further comprising an output, the logic value to be sent to the output, the second circuit further comprising an output masking circuit connected to the output, the output masking circuit to receive the logic value and to generate a second logic value, wherein the second logic value is not equal to the logic value.
